(19) United States
(12) Patent Application Publication
(10) Pub. No.: US 2020/0329585 A1
(43) Pub. Date: Oct. 15, 2020

(54) COOLING SYSTEM, IN PARTICULAR FOR ELECTRONICS CABINETS, AND ELECTRONICS CABINET WITH A COOLING SYSTEM

(71) Applicant: Pfannenberg GmbH, Hamburg (DE)

(72) Inventors: Russell Fuller, Lancaster, NY (US); Peter Starp, Hamburg (DE); Christopher Marlow, Lancaster, NY (US); Nils Peter Halm, Hamburg (DE)

(73) Assignee: Pfannenberg GmbH, Hamburg (DE)

(21) Appl. No.: 16/842,876

(22) Filed: Apr. 8, 2020

(30) Foreign Application Priority Data
Apr. 9, 2019 (EP) 19168055.2

(51) Int. Cl. H05K 7/20

(52) U.S. Cl. CPC H05K 7/20354; H05K 7/20381; H05K 7/20309; H05K 7/20318

(57) ABSTRACT

A cooling system, in particular for electronics cabinets, comprising a casing, wherein the cooling system comprises a first cooling circuit and a second cooling circuit, the first cooling circuit comprising a heat releasing section and the second cooling circuit comprising a heat releasing section, is provided, wherein the casing comprises at least three compartments including a cabinet side compartment, a first external side compartment and a second external side compartment, wherein the three compartments are fluidically separated from each other so that respective airflows in the cabinet side compartment, the first external side compartment and the second external side compartment do not mix, wherein the heat releasing section of the first cooling circuit is arranged in the first external side compartment and wherein the heat releasing section of the second cooling circuit is arranged in the second external side compartment.

### CROSS REFERENCE TO RELATED APPLICATION

This application claims priority to European Patent Application No. 19168055.2 filed on Apr. 9, 2019, which is hereby incorporated by reference herein in its entity.

### BACKGROUND

The present invention relates to a cooling system, in particular for electronics cabinets, comprising a casing, wherein the cooling system comprises a first cooling circuit and a second cooling circuit, the first cooling circuit comprising a heat releasing section and the second cooling circuit comprising a heat releasing section. Furthermore, the present invention relates to an electronics cabinet comprising a cooling system.

### TECHNOLOGICAL BACKGROUND

Cooling systems are used in a wide range of technical applications. One particular example is the use of cooling system for cooling electronics cabinets such as switchboards, control cabinets, enclosure systems or computer systems, or generally for cooling any housing enclosing heat producing components. Such cooling systems usually comprise a cooling circuit, which can either be configured as a passive cooling circuit or as an active cooling circuit.

Prior art document WO 2014/032649 A1 discloses a switch cabinet having a cooling device which has a first closed coolant circuit and a second closed coolant circuit fluidically separated from the first coolant circuit, wherein the first coolant circuit has a refrigeration device or a chilled water unit and the second coolant circuit has a heat pipe arrangement.

WO 2014/032654 A1 discloses a heat exchanger for cooling a switch cabinet, having a first pipe system for a first coolant and a second pipe system for a second coolant, which pipe system is fluidically separated from the first pipe system, wherein the first and the second pipe systems are thermally coupled to one another.

DE 10 2012 108 108 A1 discloses a switch cabinet with a cooling device comprising a first airflow path, through which ambient air is guided, and a second airflow path fluidically separated from the first airflow path and through which air from an interior of the switch cabinet is guided. A first section of an air-to-air heat exchanger is disposed in the first airflow path and a second section of the air-to-air heat exchanger is disposed in the second airflow path.

EP 3 407 693 A1 discloses a heat exchanger for cooling an electronic enclosure, wherein the heat exchanger has a condenser side and an evaporator side and wherein the condenser side and the evaporator side of the heat exchanger are separated from each other by a barrier.

CN 103 491 733 A discloses a cabinet with a combination of active and passive cooling systems.

In cooling systems comprising a first cooling circuit and a second cooling circuit, each of the cooling circuits having a heat absorbing section and a heat releasing section, an airflow passing over the heat absorbing section of the first cooling circuit subsequently passes over the heat absorbing section of the second cooling circuit and, similarly, an airflow passing over the heat releasing section of the first cooling circuit subsequently also passes over the heat releasing section of the second cooling circuit. The sequential arrangement of the heat absorbing sections and of the heat releasing sections of the first and the second cooling circuit in the same airflow paths results in high pressure drops requiring larger fans to work against said pressure drop.

### DISCLOSURE OF THE INVENTION: PROBLEM, SOLUTION, ADVANTAGES

It is an object of the present invention to provide a cooling system, in particular for electronics cabinets, comprising a first cooling circuit and a second cooling circuit, which provides a more efficient and less energy demanding heat transfer, in particular from the interior to the exterior of the electronics cabinet. Furthermore, it is an object of the present invention to provide an electronics cabinet providing the same benefits.

To solve the object of the invention a cooling system, in particular for electronics cabinets, is proposed, comprising a casing, wherein the cooling system comprises a first cooling circuit and a second cooling circuit, the first cooling circuit comprising a heat releasing section and the second cooling circuit comprising a heat releasing section, wherein the casing comprises at least three compartments including a cabinet side compartment, a first external side compartment and a second external side compartment, wherein the three compartments are fluidically separated from each other so that respective airflows in the cabinet side compartment, the first external side compartment and the second external side compartment do not mix, wherein the heat releasing section of the first cooling circuit is arranged in the first external side compartment and wherein the heat releasing section of the second cooling circuit is arranged in the second external side compartment.

The casing may comprise separation walls fluidically separating the at least three compartments from each other, so that respective airflows in the cabinet side compartment, the first external side compartment and the second external side compartment do not mix. Therefore, it is preferred that the separation walls between the cabinet side compartment, the first external side compartment and the second side compartment essentially completely prevent air from any one of the at least three compartments to enter any other of the at least three compartments.

The separation walls separating the three compartments maybe configured essentially gastight.

By arranging the heat releasing section of the first cooling circuit in the first external side compartment and the heat releasing section of the second cooling circuit in the second external side compartment, an airflow passing over the heat releasing section of the first cooling circuit to remove heat released by said heat releasing section does not pass over the heat releasing section of the second cooling circuit. Thus, the heat releasing section of the second cooling circuit is not warmed by the heat released from the heat releasing section of the first cooling circuit. The second cooling circuit therefore can be operated more effectively compared to prior art cooling system, in which the warming of the heat releasing section of the second cooling circuit reduces the cooling power of the second cooling circuit. In addition, since the airflow passing over the heat releasing section of the first cooling circuit does not pass over the heat releasing section of the second cooling circuit, the pressure drop resulting from a staging of the heat releasing sections of the first and the second cooling circuit is reduced, so that fans to drive the airflows can be configured smaller and less energy consuming than in prior art.

The cooling system is preferably configured for use with electronics cabinets. However, it is within the scope of the present invention that the cooling system can be used with any housing enclosing heat producing components.

Preferably the cabinet side compartment is fluidically connectable or connected to an interior of an electronics cabinet, and/or the first external side compartment is fluidically connectable or connected to an exterior of an electronics cabinet, and/or the second external side compartment is fluidically connectable or connected to an exterior of an electronics cabinet.

The cabinet side compartment may comprise an inlet and an outlet opening for air from an interior of an electronics cabinet to enter and exit the cabinet side compartment.

When the cooling system is connected to an electronics cabinet, heated air from the interior of the electronics cabinet may enter the cabinet side compartment through the inlet opening and exit the cabinet side compartment through the outlet opening to return to the interior of the electronics cabinet.

Similarly, the first and the second external side compartments may comprise respective inlet and outlet openings for exterior or ambient air to enter the first or second external side compartment through the respective inlet opening and to exit the first or the second external side compartment through the respective outlet opening.

Thus, heated air from the interior of the electronics cabinet can circulate through the cabinet side compartment and external or ambient air can circulate independently through the first external side compartment and the second external side compartment without the airflows in the cabinet side compartment, the first external side compartment and the second external side compartment mixing.

Preferably the first cooling circuit is a passive cooling circuit, in particular a heat pipe, a thermosiphon, or a pulsating heat pipe, wherein the heat releasing section of the first cooling circuit furthermore preferably is a condensing side of the passive cooling circuit.

However, the first cooling circuit may also be configured as a fluid cooling circuit such as a water cooling circuit or any other passive cooling circuit.

The second cooling circuit may be configured as an active cooling circuit, in particular a vapor compression cycle circuit, wherein preferably the heat releasing section of the second cooling circuit is a condenser of the active cooling circuit.

In context of the present invention, an active cooling circuit is a cooling circuit that requires the use of energy to transfer heat, for example from a region of a lower temperature to a region of higher temperature. An example for an active cooling circuit is a vapor compression cycle cooling circuit. Thus, an active cooling circuit is a cooling circuit that may comprise a compressor or the like. In contrast, a passive cooling circuit is a cooling circuit that transfers heat from a region of higher temperature to a region of lower temperature spontaneously. Examples of passive cooling systems are heat pipes, thermosiphons, pulsating heat pipes or water cooling systems. Passive cooling system may include supporting components requiring auxiliary energy such as fans or, in particular in the case of water cooling systems, pumps to circulate a coolant or refrigerant. However, the auxiliary energy used in these systems is only required to drive the supporting components, while the heat flow is strictly passive and spontaneous from the region of higher temperature to the region of lower temperature.

It is particularly preferred that the first cooling circuit is a passive cooling circuit and that the second cooling circuit as an active cooling circuit. The combination of a passive cooling circuit with an active cooling circuit allows for an efficient operation of the cooling system.

For example, when the interior temperature of the electronics cabinet is higher than the exterior or ambient temperature only the passive cooling circuit of the cooling system may be operated. If expedient, the active cooling circuit can be operated additionally as a supporting cooling circuit. When the interior temperature of the electronics cabinet is lower than the exterior or ambient temperature only the active cooling circuit is operated.

Preferably the first cooling circuit comprises a heat absorbing section, and/or the second cooling circuit comprises a heat absorbing section.

Further preferably, the heat absorbing section of the first cooling circuit and the heat absorbing section of the second cooling circuit are arranged in the cabinet side compartment, wherein still further preferably the heat absorbing section of the first cooling circuit is disposed in the direction of an airflow in the cabinet side compartment in front of the heat absorbing section of the second cooling circuit.

When in operation, an airflow will be generated or develop in the cabinet side compartment of the cooling system. Air can flow through an inlet opening into the cabinet side compartment, circulate through the cabinet side compartment and leave the cabinet side compartment through an outlet opening. With regard to the direction of the airflow in the cabinet side compartment, the heat absorbing section of the first cooling circuit can be disposed in front of the heat absorbing section of the second cooling circuit. In particular, when the heat absorbing section of the first cooling circuit is an evaporating side of a passive cooling circuit such as a heat pipe, a pulsating heat pipe or a thermosiphon, and when the heat absorbing section of the second cooling circuit is an evaporator of an active cooling circuit such as a vapor compression cycle circuit, the arrangement of the heat absorbing section of the first cooling circuit in front of the heat absorbing section of the second cooling circuit is particularly beneficial. Since the heated air from the interior of the electronics cabinet passing over the evaporating side of the passive first cooling circuit has not been cooled by the evaporator of the active second cooling circuit, the first passive cooling circuit is subjected to a high temperature delta between the interior of the electronics cabinet and the ambient or exterior air of the electronics cabinet. Thus, the first cooling circuit can remove heat more efficiently.

Alternatively, the heat absorbing section of the first cooling circuit may be arranged in the cabinet side compartment and the heat absorbing section of the second cooling circuit may be arranged in the first external side compartment and thermally coupled to the heat releasing section of the first cooling circuit.

Such an embodiment of the cooling system of the present application is disclosed in the European patent application no. 19168029.7 of the applicant, the contents of which are hereby incorporated by reference. Furthermore, a heat absorbing section of a second cooling circuit thermally coupled to a heat releasing section of a first cooling circuit in a heat exchanger arrangement suitable for the cooling system of the invention is disclosed in the European patent application no. 19168012.3 of the applicant, the contents of which are hereby incorporated by reference.

By thermally coupling the heat releasing section of the first cooling circuit to the heat absorbing section of the second cooling circuit the cooling system can be operated advantageously in a first or passive mode, a second or hybrid mode and a third or active mode, in particular when the first cooling circuit is a passive cooling circuit and when the second cooling circuit is a an active cooling circuit. For example, when the interior temperature of the electronics cabinet is higher than the exterior or ambient temperature by a sufficient temperature delta for the first passive cooling circuit to work effectively, the cooling system may be operated in the passive mode only with the passive cooling circuit. When the interior temperature of the electronics cabinet is higher than the exterior or ambient temperature only by a temperature delta not sufficient for the first passive cooling circuit to work effectively, the second active cooling circuit can be operated in a hybrid mode to increase the cooling power of the cooling system. The hybrid mode is most advantageous when the first cooling circuit is configured as a thermosiphon, a heat pipe or pulsating heat pipe and when the second cooling circuit is configured as a vapor compression cycle circuit. The evaporator or heat absorbing section of the active cooling circuit in the hybrid mode cools the condensing side or heat releasing section of the heat pipe, thermosiphon or pulsating heat pipe, thereby lowering the temperature of the coolant or refrigerant in the heat pipe, thermosiphon or pulsating heat pipe. Since the temperature of the coolant or refrigerant in the heat pipe, thermosiphon or pulsating heat pipe is substantially homogeneous, the lower temperature of the coolant or refrigerant results in a lower temperature of the evaporating side or heat absorbing section of the heat pipe, thermosiphon or pulsating heat pipe. By lowering the temperature of the evaporating side or heat absorbing section of the passive cooling circuit the cooling power of the passive cooling circuit is increased. When the interior temperature of the electronics cabinet is lower than the exterior or ambient temperature, the cooling system can be operated in the active mode using only the active cooling circuit.

Preferably the cabinet side compartment comprises a fan configured to generate the airflow in the cabinet side compartment and/or the first external side compartment comprises a fan configured to generate an airflow in the first external side compartment and/or the second external side compartment comprises a fan configured to generate an airflow in the second external side compartment.

Thus, each of the cabinet side compartment, first external side compartment and second external side compartment can comprise a fan to generate a respective airflow though the respective compartment.

Still further, it is preferred that the fan of the cabinet side compartment is disposed in the direction of the airflow in the cabinet side compartment in front of or behind the heat absorbing section of the first cooling circuit and/or in front of or behind the heat absorbing section of the second cooling circuit, and/or that the fan of the first external side compartment is disposed in the direction of the airflow in the first external side compartment in front of or behind the heat releasing section of the first cooling circuit and/or in front of or behind the heat absorbing section of the second cooling circuit, and/or that the fan of the second external side compartment is disposed in the direction of the airflow in the second external side compartment in front of or behind the heat releasing section of the second cooling circuit.

In a configuration, in which the heat absorbing section of the first cooling circuit and the heat absorbing section of the second cooling circuit are both arranged in the cabinet side compartment, the fan in the cabinet side compartment may therefore be disposed in the direction of the airflow in front of or behind both heat absorbing sections or between the heat absorbing section of the first cooling circuit and the heat absorbing section of the second cooling circuit. In this configuration the fan in the first external side compartment may be disposed in front of or behind the heat releasing section of the first cooling circuit and the fan in the second external side compartment may be disposed in the direction of the airflow in front of or behind the heat releasing section of the second cooling circuit.

In a configuration in which the heat absorbing section of the second cooling circuit is arranged in the first external side compartment and thermally coupled to the heat releasing section of the first cooling circuit, the fan in the first external side compartment may be disposed in front of or behind both the heat releasing section of the first cooling circuit and the heat absorbing section of the second cooling circuit or the fan may be disposed between the heat releasing section of the first cooling circuit and the heat absorbing section of the second cooling circuit.

A further solution to the object of the present invention is the provision of an electronics cabinet comprising a cooling system as described above.

### SHORT DESCRIPTION OF THE FIGURES

The present invention is illustrated with reference to the accompanying figures:

FIG. 1 shows a first configuration of a cooling system connected to an electronics cabinet,

FIG. 2 shows a second configuration of a cooling system connected to an electronics cabinet,

FIG. 3 shows a third configuration of a cooling system connected to an electronics cabinet, and

FIG. 4 shows a fourth configuration of a cooling system connected to an electronics cabinet.

### DETAILED DESCRIPTION OF THE FIGURES

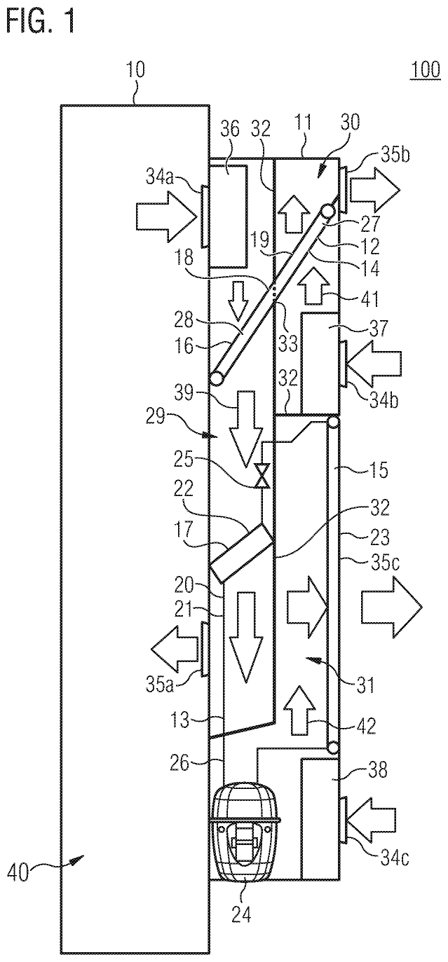

The cooling systems 100 shown in FIGS. 1 to 4 are exemplary configurations and do not in any way limit the scope of the invention. The person of ordinary skill in the art will understand that other configurations as those shown in FIGS. 1 to 4 are within the scope of the invention.

FIG. 1 shows a cooling system 100. The cooling system is connected to an electronics cabinet 10. The cooling system comprises a casing 11, a first cooling circuit 12 and a second cooling circuit 13. The first cooling circuit 12 comprises a heat releasing section 14. The second cooling circuit 13 also comprises a heat releasing section 15. In addition, the first cooling circuit 12 comprises a heat absorbing section 16 and the second cooling circuit 13 comprises a heat absorbing section 17. The first cooling circuit is configured as a passive cooling circuit 18 and, more particularly, as a pulsating heat pipe 19. The second cooling circuit 13 is configured as an active cooling circuit 20 and, more particularly, as a vapor compression cycle circuit 21. The vapor compression cycle circuit 21 comprises an evaporator 22, a condenser 23, a compressor 24, an expansion valve 25 and fluid lines 26 to interconnect these components. The condenser 23 is the heat releasing section 15 of the second cooling circuit 13 and the evaporator 22 is the heat absorbing section 17 of the second cooling circuit 13. Similarly, the pulsating heat pipe 19 comprises a condensing side 27 as the heat releasing section 14 of the first cooling circuit 12 and an evaporating side 28 as the heat absorbing section 16 of the first cooling circuit 12.

The casing 11 of the cooling system 100 is subdivided into a cabinet side compartment 29, a first external side compartment 30 and a second external side compartment 31. The cabinet side compartment 29, the first external side compartment 30 and the second external side compartment 31 are separated from each other by essentially gastight separation walls 32. The heat releasing section 14 of the first cooling circuit 12 is arranged in the first external side compartment 30 and the heat absorbing section 16 of the first cooling circuit 12 is arranged in the cabinet side compartment 29. Since the first cooling circuit 12 is configured as a pulsating heat pipe 19, the pulsating heat pipe 19 “sticks” through the separation wall 32 between the cabinet side compartment 29 and the first external side compartment 30. To prevent air from the cabinet side compartment 29 to enter the first external side compartment 30 a seal 33 is provided in the separation wall 32 separating the cabinet side compartment 29 and the first external side compartment 30 and surrounding the pulsating heat pipe 19. Furthermore, the heat absorbing section 17 of the second cooling circuit 13 is disposed in the cabinet side compartment 29 and the heat releasing section 15 of the second cooling circuit 13 is disposed in the second external side compartment 31. Each of the cabinet side compartment 29, the first external side compartment 30 and the second external side compartment 31 comprises respective inlet openings 34a, 34b, 34c and outlet openings 35a, 35b, 35c. A first fan 36 is disposed in the cabinet side compartment 29. A second fan 37 is disposed in the first external side compartment 30 and a third fan 38 is disposed in the second external side compartment 31. As indicated with arrows, fan 36 generates an airflow 39 in the cabinet side compartment 29 by driving air from an interior 40 of the electronics cabinet 10 through the inlet opening 34a of the cabinet side compartment 29. Airflow 39 passes over the heat absorbing section 16 of the first cooling circuit 12 and the heat absorbing section 17 of the second cooling circuit 13 and leaves the cabinet side compartment 29 via outlet opening 35a. Fan 36 is disposed in the direction of the airflow 39 in front of the heat absorbing section 16 of the first cooling circuit 12 and the heat absorbing section 17 of the second cooling circuit 13. Furthermore, with regard to the direction of airflow 39, the heat absorbing section 16 of the first cooling circuit 12 is disposed in front of the heat absorbing section 17 of the second cooling circuit 13. Similarly, fan 37 generates an airflow 41 in the first external side compartment 30. Ambient or external air enters the first external side compartment 30 through inlet opening 34b and exits the first external side compartment 30 through outlet opening 35b. The airflow 41 in the first external side compartment 30 passes over the heat releasing section 14 of the first cooling circuit 12. Thus, heat absorbed from the airflow 39 in the cabinet side compartment 29 by the heat absorbing section 16 is transferred to the heat releasing section 14 of the first cooling circuit 12 in the first external side compartment 30 and released to the ambient air via airflow 41. Fan 38 in the second external side compartment 31 generates airflow 42 in the second external side compartment 31. Ambient or external air enters the second external side compartment 31 via inlet opening 34c and exits the second external side compartment 31 via outlet opening 35c. Airflow 42 passes over the heat releasing section 15 of the second cooling circuit 13 so that heat absorbed by the heat absorbing section 17 from the airflow 39 in the cabinet side compartment 29 is released to the exterior via the heat releasing section 15 of the second cooling circuit 13. Both fans 37 and 38 are disposed with regard to the directions of the airflows 41 and 42 in front of the heat releasing section 14 of the first cooling circuit 12 and the heat releasing section 15 of the second cooling circuit 13, respectively.

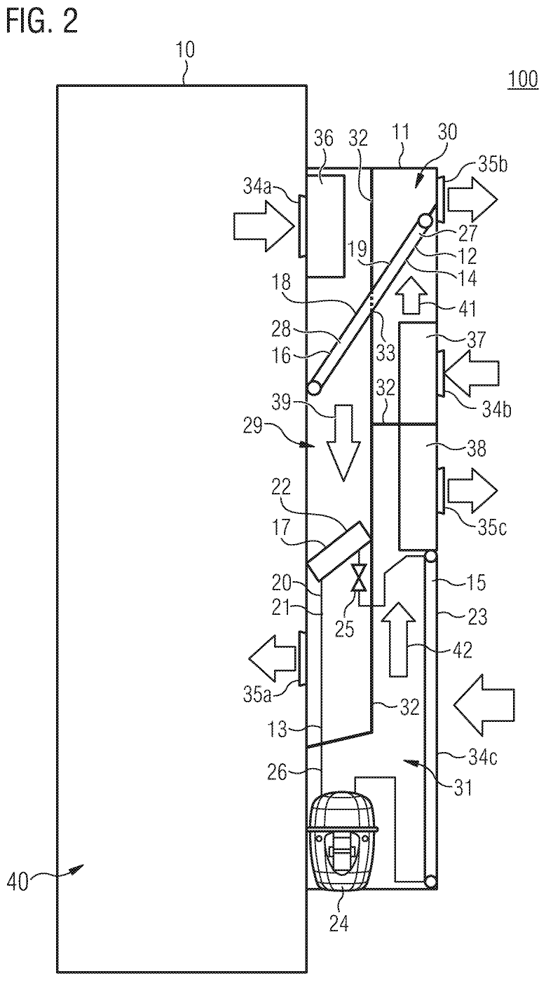

FIG. 2 shows a second configuration of a cooling system 100. The cooling system 100 is attached to an electronics cabinet 10. The cooling system 100 of FIG. 2 is essentially identical to the cooling system 100 of FIG. 1 and like reference numerals refer to corresponding components. The only difference between the cooling system 100 of FIG. 2 and the cooling system 100 of FIG. 1 is that second fan 38 in the second external side compartment 31 is disposed in the direction of the airflow 42 behind the heat releasing section 15 of the second cooling circuit 13.

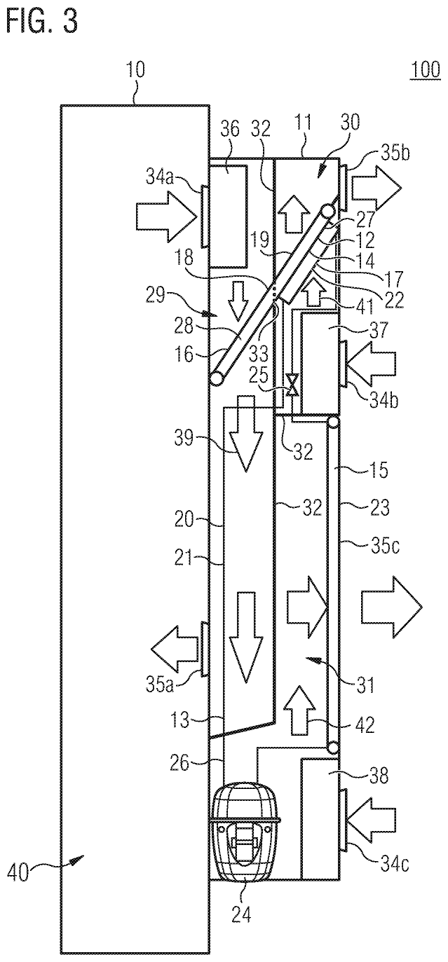

FIG. 3 shows a third configuration of the cooling system 100, which is similar to the cooling systems 100 of FIG. 1. Like reference numerals refer to corresponding components. In contrast to the cooling system 100 of FIG. 1 in the cooling system 100 of FIG. 3 the heat absorbing section 17 of the second cooling circuit 13 is not disposed in the cabinet side compartment 29, but is arranged in the first external side compartment 30 and thermally coupled to the heat releasing section 14 of the first cooling circuit 12. Thus, the heat absorbing section 17 of the second cooling circuit 13 cools the heat releasing section 14 of the first cooling circuit 12. In the configuration of FIG. 3 the first cooling circuit 12 is configured as a pulsating heat pipe 19 and the second cooling circuit 13 is configured as a vapor compression cycle circuit 21. The cooling system 100 of FIG. 3 can be particularly advantageously operated in the so-called hybrid mode when the interior temperature of the electronics cabinet 10 is higher than the exterior or ambient temperature only by a temperature delta not sufficient for the pulsating heat pipe 19 to work effectively. In this case, the evaporator 22 of the vapor compression cycle circuit 21 is used to cool the condensing side 27 of the pulsating heat pipe 19 and thereby lowers the temperature of a coolant or refrigerant in the pulsating heat pipe 19. Since the temperature of the refrigerant or coolant in the pulsating heat pipe 19 is essentially homogeneous over the full length of the pulsating heat pipe 19, the evaporating side 28 of the pulsating heat pipe 19 is cooled as well and thereby the efficiency of the pulsating heat pipe 19 is increased.

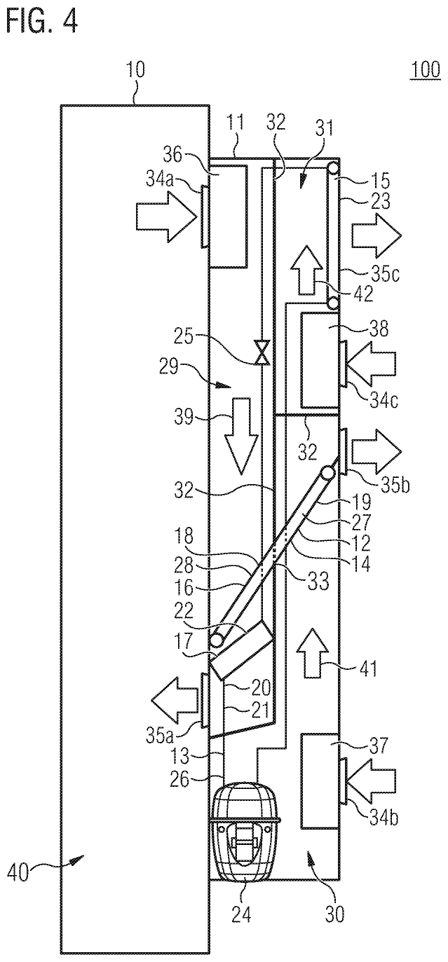

FIG. 4 shows a fourth configuration of the cooling system 100, which is similar to the cooling systems 100 of FIG. 1. Like reference numerals refer to corresponding components. In contrast to the cooling system of FIG. 1, in the cooling system 100 of FIG. 4 the first external side compartment 30 and the second side external compartment 31 are swapped, i.e. in the cooling system 100 of FIG. 4 the first external side compartment 30 is located below the second side external compartment 31, while in FIG. 1 the first external side compartment 30 is located above the second side external compartment 31. In the configuration of FIG. 1 warm air from airflow 42 can exit second external side compartment 31 through outlet opening 35c and enter first external side compartment 30 through inlet opening 34b. This short circuiting of warm airflows 42 and 41 can result in a warming of the condensing side 27 of pulsating heat pipe 19. Since the pulsating heat pipe 19 is a passive cooling circuit 18, warming of the condensing side 27 of pulsating heat pipe 19 reduces the cooling power of the pulsating heat pipe 19. Returning to the configuration of FIG. 4, the condensing side 27 of pulsating heat pipe 19 is disposed in first external side compartment 30, which is arranged below second external side compartment 31. Thus, because warm air rises, warm air from airflow 42 from second external side compartment 31 exiting through outlet opening 35c cannot enter first external side compartment 30 through inlet opening 34b. This arrangement of first external side compartment 30 and second external side compartment 31 prevents the warming of the condensing side 27 of pulsating heat pipe 19 and therefore ensures a high cooling power of the passive cooling circuit 18 of the pulsating heat pipe 19. Although short circuiting of airflows 41, 42 is still possible, i.e. warm air from airflow 41 can exit first external side compartment 30 through outlet opening 35b and enter second external side compartment 31 through inlet opening 34c, the resulting warming of condenser 23 of vapor compression cycle circuit 21 does not considerably impact the total cooling power of cooling system 100 because the cooling power of vapor compression cycle circuit 21 can be increased by adjusting its operating parameters.

1. Cooling system, in particular for electronics cabinets, comprising a casing, wherein the cooling system comprises a first cooling circuit and a second cooling circuit, the first cooling circuit comprising a heat releasing section and the second cooling circuit comprising a heat releasing section,
wherein the casing comprises at least three compartments including a cabinet side compartment, a first external side compartment and a second external side compartment, wherein the three compartments are fluidically separated from each other so that respective airflows in the cabinet side compartment, the first external side compartment and the second external side compartment do not mix, wherein the heat releasing section of the first cooling circuit is arranged in the first external side compartment and wherein the heat releasing section of the second cooling circuit is arranged in the second external side compartment.

2. Cooling system according to claim 1, wherein the cabinet side compartment is fluidically connectable or connected to an interior of an electronics cabinet, and/or that the first external side compartment is fluidically connectable or connected to an exterior of an electronics cabinet, and/or that the second external side compartment is fluidically connectable or connected to an exterior of an electronics cabinet.

3. Cooling system according to claim 1, wherein the first cooling circuit is a passive cooling circuit, in particular a heat pipe, a thermosiphon or a pulsating heat pipe, wherein the heat releasing section of the first cooling circuit preferably is a condensing side of the passive cooling circuit.

4. Cooling system according to claim 1, wherein the second cooling circuit is an active cooling circuit, in particular a vapor compression cycle circuit, wherein the heat releasing section of the second cooling circuit is preferably a condenser of the active cooling circuit.

5. Cooling system according to claim 1, wherein the first cooling circuit comprises a heat absorbing section and/or that the second cooling circuit comprises a heat absorbing section.

6. Cooling system according to claim 5, wherein the heat absorbing section of the first cooling circuit and the heat absorbing section of the second cooling circuit are arranged in the cabinet side compartment, wherein preferably the heat absorbing section of the first cooling circuit is disposed in the direction of an airflow in the cabinet side compartment in front of the heat absorbing section of the second cooling circuit.

7. Cooling system according to claim 5, wherein the heat absorbing section of the first cooling circuit is arranged in the cabinet side compartment and that the heat absorbing section of the second cooling circuit is arranged in the first external side compartment and thermally coupled to the heat releasing section of the first cooling circuit.

8. Cooling system according to claim 1, wherein the cabinet side compartment comprises a fan configured to generate the airflow in the cabinet side compartment and/or that the first external side compartment comprises a fan configured to generate an airflow in the first external side compartment and/or that the second external side compartment comprises a fan configured to generate an airflow in the second external side compartment.

9. Cooling system according to claim 8, wherein the fan of the cabinet side compartment is disposed in the direction of the airflow in the cabinet side compartment in front of or behind the heat absorbing section of the first cooling circuit and/or in front of or behind the heat absorbing section of the second cooling circuit, and/or that the fan of the first external side compartment is disposed in the direction of the airflow in the first external side compartment in front of or behind the heat releasing section of the first cooling circuit and/or in front of or behind the heat absorbing section of the second cooling circuit, and/or that the fan of the second external side compartment is disposed in the direction of the airflow in the second external side compartment in front of or behind the heat releasing section of the second cooling circuit.

10. Electronics cabinet comprising a cooling system, in particular for electronics cabinets, comprising a casing, wherein the cooling system comprises a first cooling circuit and a second cooling circuit, the first cooling circuit comprising a heat releasing section and the second cooling circuit comprising a heat releasing section,
wherein the casing comprises at least three compartments including a cabinet side compartment, a first external side compartment and a second external side compartment, wherein the three compartments are fluidically separated from each other so that respective airflows in the cabinet side compartment, the first external side compartment and the second external side compartment do not mix, wherein the heat releasing section of the first cooling circuit is arranged in the first external side compartment and wherein the heat releasing section of the second cooling circuit is arranged in the second external side compartment.
